(19) United States
(12) Patent Application Publication
(10) Pub. No.: US 2016/0181010 A1
(43) Pub. Date: Jun. 23, 2016

(54) COMPOSITE ELECTRONIC COMPONENT

(71) Applicant: SAMSUNG ELECTRO-MECHANICS., LTD., Suwon-Si (KR)

(72) Inventor: Yu Jin CHOI, Suwon-Si (KR)

(21) Appl. No.: 14/884,692

(22) Filed: Oct. 15, 2015

(30) Foreign Application Priority Data
Dec. 23, 2014 (KR) 10-2014-0186905

(51) Int. Cl. H01F 27/40; H01G 4/232; H05K 1/18; H01G 4/30; H01F 27/28; H01F 27/24

(52) U.S. Cl. CPC H01F 27/40; H01F 27/2804; H01F 27/24; H05K 1/181; H01G 4/30; H01G 4/232

(57) ABSTRACT

A composite electronic component includes a composite body including a capacitor and an inductor bonded to each other, the capacitor including a ceramic body in which a plurality of dielectric layers and first and second internal electrodes disposed to face each other with respective dielectric layers interposed therebetween are stacked and the inductor including a magnetic body including a coil part. The inductor and the capacitor are bonded to each other by an adhesive including a thermosetting resin containing silicon dioxide (SiO₂).

### CROSS-REFERENCE TO RELATED APPLICATION

This application claims the priority and benefit of Korean Patent Application No. 10-2014-0186905 filed on Dec. 23, 2014, with the Korean Intellectual Property Office, the disclosure of which is incorporated herein by reference.

### BACKGROUND

The present disclosure relates to a composite electronic component including a plurality of passive devices and a board having the same.

With recent demand for small, light, high-performance electronic apparatuses, demand for electronic apparatuses having a significantly decreased size and a variety of functions is gradually increasing.

Such electronic apparatuses include a power semiconductor-based power management integrated circuit (PMIC) serving to efficiently control and manage limited battery resources in order to satisfy various service requirements.

However, as electronic apparatuses are increasingly provided with increased functionality, the number of DC to DC converters included in such a PMIC has increased. In addition, the number of passive devices required to be included in a power input terminal and a power output terminal of the PMIC has also increased.

In this case, the disposition area of components in electronic apparatuses may inevitably be increased, which may limit the miniaturization of electronic apparatuses.

In addition, a severe amount of noise may occur due to the PMIC and wiring patterns of circuits provided peripherally to the PMIC.

To solve the above problems, research into composite electronic components in which inductor and capacitors are bonded to each other has been undertaken to decrease the disposition area of the components in the electronic apparatuses and suppress the occurrence of noise.

Meanwhile, an adhesive has been used to bond the inductor and the capacitor as described above. However, as the adhesive is manufactured for simple bonding between two components, the inductor and the capacitor may be bonded to each other and then a distance between the inductor and the capacitor may not be maintained to be constant, such that insulation resistance (IR) may be leaked toward the inductor having a relatively low degree of insulation resistance (IR), thereby decreasing the degree of insulation resistance of the capacitor.

### SUMMARY

An aspect of the present disclosure may provide a composite electronic component having a component mounting area reduced in size in a driving power supply system and a board having the same.

Another aspect of the present disclosure may also provide a composite electronic component suppressing the occurrence of noise in a driving power supply system, and a board having the same.

According to an aspect of the present disclosure, a composite electronic component may include a composite body including a capacitor and an inductor bonded to each other, the capacitor including a ceramic body in which a plurality of dielectric layers and first and second internal electrodes disposed to face each other with respective dielectric layers interposed between the first and second internal electrodes are stacked and the inductor including a magnetic body including a coil part, an input terminal disposed on a first end surface of the composite body in a length direction and connected to the coil part of the inductor, an output terminal including a first output terminal disposed on a second end surface of the composite body in the length direction and connected to the coil part of the inductor and a second output terminal disposed on a second end surface of the composite body in the length direction and connected to the first internal electrodes of the capacitor, and a ground terminal disposed on the first end surface of the composite body in the length direction and connected to the second internal electrodes of the capacitor. The inductor and the capacitor may be bonded to each other by an adhesive including a thermosetting resin containing silicon dioxide (SiO₂).

The capacitor may be bonded to a side surface of the inductor.

According to another aspect of the present disclosure a composite electronic component may include an input terminal receiving power converted by a power manager, a power stabilizer stabilizing the received power and including a composite body including a capacitor and an inductor bonded to each other, the capacitor including a ceramic body in which a plurality of dielectric layers and first and second internal electrodes disposed to face each other with respective dielectric layers interposed between the first and second internal electrodes are stacked, the inductor including a magnetic body including a coil part, and the inductor and the capacitor being bonded to each other using an adhesive including a thermosetting resin containing silicon dioxide (SiO₂), an output terminal supplying the stabilized power, and a ground terminal for grounding.

According to another aspect of the present disclosure a board having a composite electronic component may include a printed circuit board on which three or more electrode pads are formed, the composite electronic component as described above disposed on the printed circuit board, and solders connecting the electrode pads and the composite electronic component.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a perspective view schematically illustrating a composite electronic component according to an exemplary embodiment in the present disclosure;

FIG. 2 is a perspective view schematically illustrating an interior of a composite electronic component according to a first exemplary embodiment in the present disclosure, in the composite electronic component of FIG. 1;

FIG. 3 is a perspective view schematically illustrating an interior of a composite electronic component according to a second exemplary embodiment in the present disclosure, in the composite electronic component of FIG. 1;

FIG. 4 is a perspective view schematically illustrating an interior of a composite electronic component according to a third exemplary embodiment, in the composite electronic component of FIG. 1;

FIG. 5 is a plan view illustrating internal electrodes that may be adopted in a multilayer ceramic capacitor in the composite electronic component shown in FIG. 1;

FIG. 6 is an equivalent circuit diagram of the composite electronic component shown in FIG. 1;

FIG. 7 is a view illustrating a driving power supply system supplying driving power to a predetermined terminal requiring the driving power through a battery and a power manager;

FIG. 8 is a view illustrating a disposition pattern of the driving power supply system;

FIG. 9 is a circuit diagram of the composite electronic component according to the exemplary embodiment in the present disclosure;

FIG. 10 is a view illustrating the disposition pattern of the driving power supply system to which the composite electronic component according to the exemplary embodiment in the present disclosure is applied;

FIG. 11 is a perspective view illustrating the composite electronic component of FIG. 1 being mounted on a printed circuit board; and

FIGS. 12A through 12E are scanning electron microscope photographs illustrating a bonded interface between an inductor and a capacitor according to Inventive Examples and a Comparative Example of the present disclosure.

### DETAILED DESCRIPTION

Hereinafter, embodiments of the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

### Composite Electronic Component

Hereinafter, exemplary embodiments in the present disclosure will be described in detail with reference to the accompanying drawings.

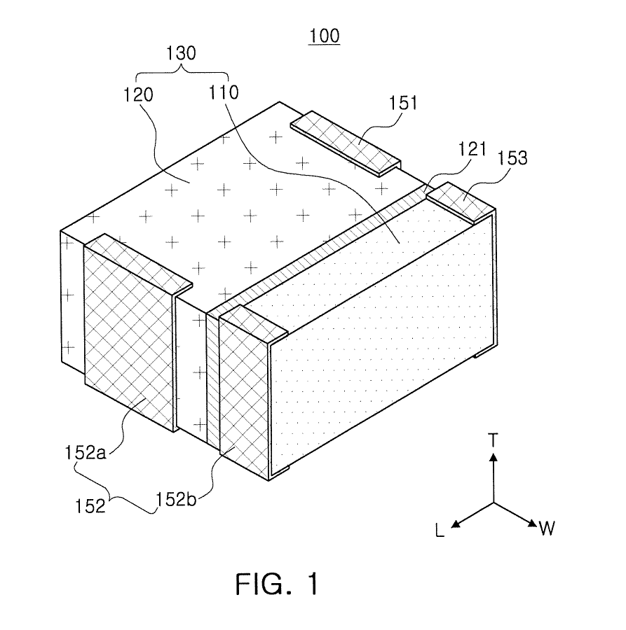

FIG. 1 is a perspective view schematically illustrating a composite electronic component according to an exemplary embodiment in the present disclosure.

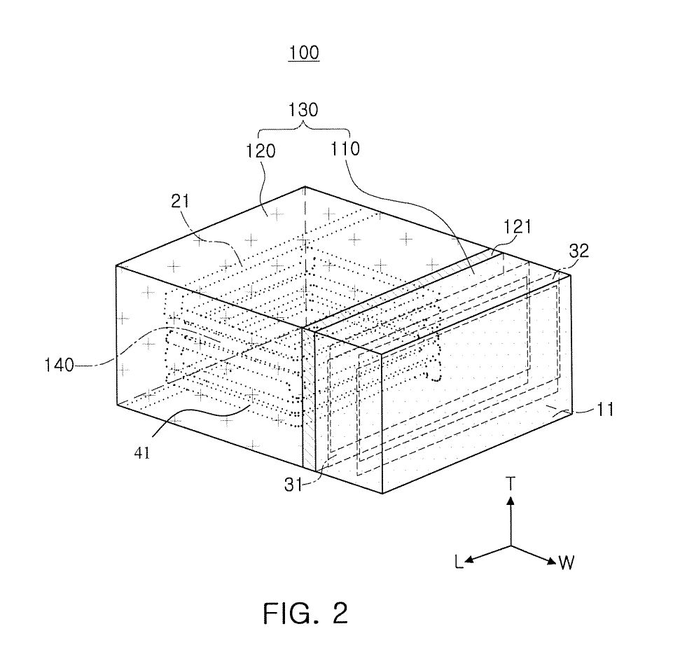

FIG. 2 is a perspective view schematically illustrating an interior of a composite electronic component according to a first exemplary embodiment in the present disclosure, in the composite electronic component of FIG. 1.

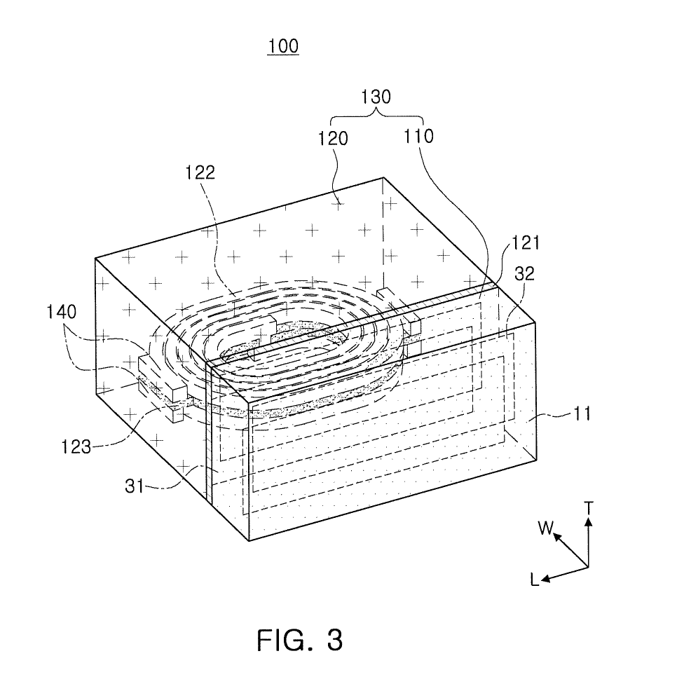

FIG. 3 is a perspective view schematically illustrating an interior of a composite electronic component according to a second exemplary embodiment in the present disclosure, in the composite electronic component of FIG. 1.

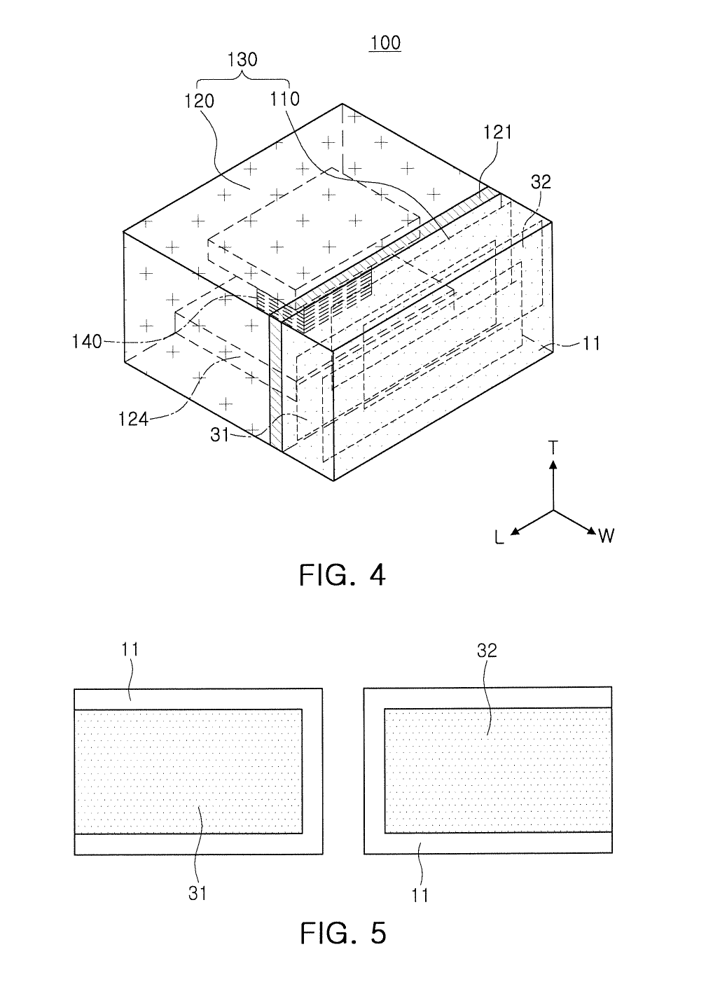

FIG. 4 is a perspective view schematically illustrating an interior of a composite electronic component according to a third exemplary embodiment in the present disclosure, in the composite electronic component of FIG. 1.

FIG. 5 is a plan view illustrating internal electrodes that may be adopted in a multilayer ceramic capacitor in the composite electronic component shown in FIG. 1.

Referring to FIG. 1, in the composite electronic component according to an exemplary embodiment in the present disclosure, a ‘length direction’ refers to an ‘L’ direction of FIG. 1, a ‘width direction’ refers to a ‘W’ direction of FIG. 1, and a ‘thickness direction’ refers to a ‘T’ direction of FIG. 1. Here, the ‘thickness direction’ refers to a direction in which dielectric layers of a capacitor are stacked, for instance, a ‘stacked direction’.

Meanwhile, the length direction, the width direction, and the thickness direction of the composite electronic component are the same as those of a capacitor and an inductor as described below.

In addition, in an exemplary embodiment in the present disclosure, the composite electronic component may have top and bottom surfaces opposing each other, and first and second end surfaces connecting the top and bottom surfaces and disposed in the length direction and first and second side surfaces connecting the top and bottom surfaces and disposed in the width direction. A shape of the composite electronic component is not particularly limited, but may be a hexahedral shape as shown.

In addition, the first and second end surfaces of the composite electronic component in the length direction and the first and second side surfaces thereof in the width direction may be the same as first and second end surfaces of a capacitor and an inductor in the length direction and first and second end surfaces thereof in the width direction, respectively, as described below.

Meanwhile, the composite electronic component may have a form in which the capacitor and the inductor are bonded to each other. In the case in which the capacitor is bonded to the side surface of the inductor, an upper surface of the composite electronic component refers to an upper surface of the inductor and the capacitor and a lower surface thereof refers to a lower surface of the inductor and the capacitor.

Referring to FIGS. 1 through 5, a composite electronic component 100 according to an exemplary embodiment in the present disclosure may include a composite body 130 having a capacitor 110 and an inductor 120 bonded to each other, the capacitor 110 including a ceramic body in which a plurality of dielectric layers 11 and first and second internal electrodes 31 and 32 disposed to face each other with respective dielectric layers 11 interposed therebetween are stacked and the inductor 120 including a magnetic body including a coil part 140.

In the present exemplary embodiment, the composite body 130 may have top and bottom surfaces opposing each other, and first and second end surfaces in a length direction and first and second side surfaces in a width direction connecting the top and bottom surfaces.

A shape of the composite body 130 is not particularly limited, but may be a hexahedral shape as illustrated.

Meanwhile, according to an exemplary embodiment in the present disclosure, the capacitor 110 may be bonded to the side surfaces of the inductor 120, but is not limited thereto. Therefore, the inductor 120 may be disposed in various forms.

The composite body 130 may be formed by bonding between the capacitor 110 and the inductor 120. However, a method of forming the composite body 130 is not particularly limited.

According to the exemplary embodiment in the present disclosure, the inductor 120 and the capacitor 110 are bonded to each other using an adhesive 121 including thermosetting resin to which silicon dioxide (SiO₂) is added.

The adhesive 121 includes the thermosetting resin to which silicon dioxide (SiO₂) is added to constantly maintain the distance between the inductor and the capacitor at the time of the bonding process, thereby avoiding the reduction in the insulation resistance (IR).

Generally, research into composite electronic components in which the inductor and the capacitor are bonded to each other has been conducted to decrease a disposition area of the components in the electronic apparatuses and suppress the occurrence of noise.

Meanwhile, the adhesive has been used to bond the inductor and the capacitor as described above. However, the adhesive is manufactured for simple bonding between two components, the inductor and the capacitor are bonded to each other and then a distance between two components is not constantly maintained, such that the insulation resistance (IR) is leaked toward the inductor having a relatively lower insulation resistance, thereby causing the problem in that the insulation resistance of the capacitor is decreased.

According to the exemplary embodiment in the present disclosure, the inductor and the capacitor are bonded to each other by the adhesive 121 including the thermosetting resin to which the silicon dioxide (SiO₂) is added and thus the adhesive 121 serves as a spacer between the bonded components, thereby preventing the insulation resistance of the capacitor from decreasing even after the products are bonded to each other.

For instance, the adhesive 121 includes the thermosetting resin to which the silicon dioxide (SiO₂) is added and thus particles of the silicon dioxide (SiO₂) are positioned at a bonded interface between the inductor 120 and the capacitor 110, thereby preventing the inductor 120 and the capacitor 110 from contacting each other.

As a result, it is possible to prevent the problem in that the insulation resistance of the capacitor is decreased due to the leakage of the insulating resistance (IR) to the inductor having relatively lower insulation resistance.

Therefore, according to the exemplary embodiment in the present disclosure, the inductor 120 and the capacitor 110 may be bonded to each other while being spaced apart from each other by disposing the adhesive 121 including the thermosetting resin to which silicon dioxide (SiO₂) is added at the bonded interface.

The thermosetting resin may be epoxy resin but is not limited thereto. Therefore, any resin may be used as long as resin may bond two components.

A content of the silicon dioxide (SiO₂) is not particularly limited, but 20 to 50 wt % of silicon dioxide (SiO₂) may be added to prevent the insulation resistance from decreasing and obtain the bonding effect of the two components as described above.

20 to 50 wt % of silicon dioxide (SiO₂) may be included in the adhesive 121, but when 30 to 40 wt % of silicon dioxide (SiO₂) is included in the adhesive 121, the contact between the inductor and the capacitor may be suppressed to prevent the insulation resistance from decreasing and obtain the excellent bonding effect.

When the content of the silicon dioxide (SiO₂) is less than 20 wt %, the effect of suppressing contact between the inductor and the capacitor is limited and thus insulation resistance is leaked toward the inductor having relatively lower insulation resistance (IR), thereby decreasing insulation resistance of the capacitor.

On the other hand, when the content of the silicon dioxide (SiO₂) exceeds 50 wt %, the content of the silicon dioxide (SiO₂) may be too high and thus the bonding effect between the inductor and the capacitor may be decreased, thereby causing defects.

Hereinafter, the capacitor 110 and the inductor 120 configuring the composite body 130 will be described below in detail.

According to the exemplary embodiment in the present disclosure, the magnetic body configuring the inductor 120 may include the coil part 140.

The inductor 120 is not particularly limited and may be, for example a multilayer-type inductor, a thin film-type inductor, and a wire wound inductor.

The multilayer-type inductor may be manufactured by printing electrodes thickly on thin ferrite or glass ceramic sheets, stacking several sheets on which coil patterns are printed, and connecting internal conductive wires through via-holes.

The thin film-type inductor may be manufactured by forming conductive coil wires on a ceramic substrate by thin film sputtering or plating and filling a ferrite material.

The wire wound inductor may be manufactured by winding wires (conductive coil wires) around a core.

Referring to FIG. 2, in a composite electronic component 100 according to a first exemplary embodiment in the present disclosure, the inductor 120 may be the multilayer-type inductor.

In detail, the magnetic body may have a form in which a plurality of magnetic layers 21 having conductive patterns 41 formed thereon are stacked, in which the conductive patterns 41 may configure the coil part 140.

Referring to FIG. 3, in a composite electronic component 100 according to a second exemplary embodiment in the present disclosure, the inductor 120 may be the thin film-type inductor.

In detail, the inductor 120 may have a thin film form in which the magnetic body includes an insulating substrate 123 and coils formed on at least one surface of the insulating substrate 123.

The magnetic body may be formed by filling top and bottom portions of the insulating substrate 123 having the coils formed on at least one surface thereof with magnetic materials 122.

Referring to FIG. 4, in a composite electronic component 100 according to a third exemplary embodiment in the present disclosure, the inductor 120 may be the wire wound inductor.

In detail, the inductor 120 may have a form in which the magnetic body includes a core 124 and winding coils wound around the core 124.

Referring to FIGS. 2 through 4, the first and second internal electrodes 31 and 32 of the capacitor 110 are stacked vertically with respect to a mounting surface but are not limited thereto. Therefore, the first and second internal electrodes 31 and 32 of the capacitor 110 may be stacked to be parallel to the mounting surface.

The magnetic layer 21 and the magnetic material 122 may be formed of an Ni—Cu—Zn based material, an Ni—Cu—Zn—Mg based material, or an Mn—Zn based material, but are not limited thereto.

According to an exemplary embodiment in the present disclosure, the inductor 120 may be a power inductor that may be applied to a large amount of current.

The power inductor may be a high efficiency inductor of which the inductance is less changed than a general inductor when a DC current is applied thereto. For instance, the power inductor may include DC bias characteristics (change in inductance depending on the applied DC current) as well as a function of a general inductor.

For instance, the composite electronic component according to an exemplary embodiment in the present disclosure is used in the power management integrated circuit (PMIC) and may include the power inductor which is the high efficiency inductor of which the inductance is less changed than a general inductor when the DC current is applied thereto.

Meanwhile, the ceramic body configuring the capacitor 110 may be formed by stacking the plurality of dielectric layers 11, and the plurality of internal electrodes (first and second internal electrodes 31 and 32 in order) may be disposed in the ceramic body to be spaced apart from each other with respective dielectric layers interposed therebetween.

The dielectric layer 11 may be formed by sintering a ceramic green sheet including a ceramic powder, an organic solvent, and an organic binder. The ceramic powder which is a high-k material may be a barium titanate (BaTiO₃) based material, a strontium titanate (SrTiO₃) based material, or the like, but is not limited thereto.

Meanwhile, according to the exemplary embodiment in the present disclosure, the first internal electrode 31 may be exposed to a second end surface of the composite body 130 in a length direction and the second internal electrode 32 may be exposed to a first end surface of the composite body 130 in a length direction but is not necessarily limited thereto.

According to the exemplary embodiment in the present disclosure, the first and second internal electrodes 31 and 32 may be formed of a conductive paste including a conductive metal.

The conductive metal may be nickel (Ni), copper (Cu), palladium (Pd), or alloys thereof, but is not limited thereto.

The first and second internal electrodes 31 and 32 may be printed on the ceramic green sheets forming the dielectric layer 11, using the conductive paste by printing methods such as a screen printing method or a gravure printing method.

The ceramic green sheets having the internal electrodes printed thereon may be alternately stacked and sintered to form the ceramic body.

Pattern shapes of the first and second internal electrodes 31 and 32 are illustrated in FIG. 5 but are not limited thereto. Therefore, the pattern shapes of the first and second internal electrodes 31 and 32 may be variously changed.

The capacitor may serve to control a voltage supplied from a power management integrated circuit (PMIC).

The composite electronic component 100 according to the exemplary embodiment in the present disclosure may include an input terminal 151 disposed on the first end surface of the composite body 130 in the length direction and connected to the coil part 140 of the inductor 120, an output terminal 152 including a first output terminal 152a disposed on the second end surface of the composite body 130 in the length direction and connected to the coil part 140 of the inductor 120 and a second output terminal 152b disposed on the second end surface of the composite body 130 in the length direction and connected to the first internal electrodes 31 of the capacitor 110, and a ground terminal 153 disposed on the first end surface of the composite body 130 in the length direction and connected to the second internal electrodes 32 of the capacitor 110.

The input terminal 151 and the first output terminal 152a may be connected to the coil part 140 of the inductor 120 to serve as the inductor in the composite electronic component 100.

In addition, the second output terminal 152b is connected to the first internal electrodes 31 of the capacitor 110 and the second internal electrodes 32 of the capacitor 110 are connected to the ground terminal 153 to serve as the capacitor in the composite electronic component 100.

The input terminal 151, the output terminal 152, and the ground terminal 153 may be formed of a conductive paste including a conductive metal.

The conductive metal may be nickel (Ni), copper (Cu), tin (Sn), or alloys thereof, but is not limited thereto.

The conductive paste may further include an insulating material. For example, the insulating material may be glass, but is not limited thereto.

A method of forming the input terminal 151, the output terminal 152, and the ground terminal 153 is not particularly limited. Therefore, the input terminal 151, the output terminal 152, and the ground terminal 153 may be formed by dipping the ceramic body or be formed by other methods such as a printing method, a plating method, or the like.

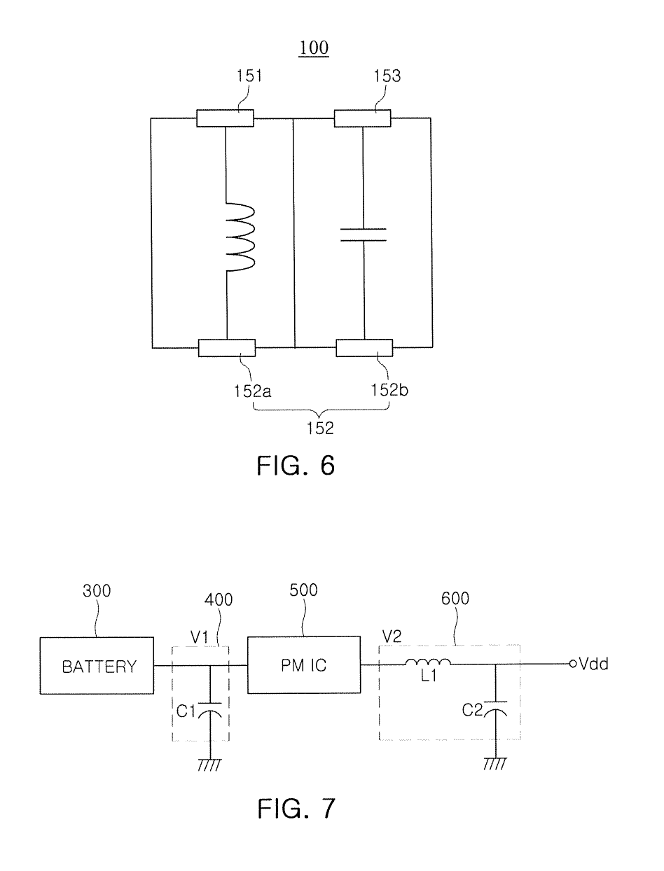

FIG. 6 is an equivalent circuit diagram of the composite electronic component illustrated in FIG. 1.

Referring to FIG. 6, the composite electronic component according to an exemplary embodiment in the present disclosure may include the inductor 120 and the capacitor 110 bonded to each other unlike the related art. Therefore, the inductor 120 and the capacitor 110 may be designed so as to have the shortest distance therebetween, thereby decreasing noise.

In addition, the inductor 120 and the capacitor 110 are bonded to each other to significantly decrease the area required for the mounting thereof in the PMIC, thereby easily securing the mounting space.

In addition, costs required for mounting the composite electronic component may be decreased.

Meanwhile, as the electronic apparatuses include various functions, the number of DC to DC converters included in the PMIC has increased. In addition, the number of passive devices that should be included in a power input terminal and a power output terminal of the PMIC has also increased.

In this case, the disposition area of components in the electronic apparatuses may inevitably be increased, which may limit miniaturization of the electronic apparatuses.

In addition, severe noise may occur due to the PMIC and wiring patterns of peripheral circuits of the PMIC.

To solve the above problems, research into a composite electronic component in which an inductor and a capacitor are vertically bonded to each other have been conducted to decrease the disposition area of the components in the electronic apparatuses and suppress the occurrence of noise.

However, when the inductor and the capacitor are vertically disposed as described above, magnetic flux, generated from the inductor, affects the internal electrodes of the capacitor, thereby causing a problem in that the self resonant frequency (SRF) moves toward a low frequency.

When the self resonant frequency (SRF) moves to the low frequency as described above, there may be a problem in that a frequency domain of the inductor which may be used in the exemplary embodiment in the present disclosure is narrow.

For instance, since the function of the inductor is not revealed in a high frequency band which is equal to or higher than the self resonant frequency (SRF), the self resonant frequency (SRF) moves to the low frequency, such that there may be a problem in that the available frequency band is limited.

However, according to the exemplary embodiment in the present disclosure, the capacitor 110 may be bonded to the side surface of the inductor 120 to significantly decrease the effect of the magnetic flux generated from the inductor on the internal electrodes of the capacitor, thereby preventing the self resonant frequency (SRF) from being changed, since the coil part 140 is wounded around an axis parallel to the adhesive 121.

For instance, according to the exemplary embodiment in the present disclosure, the inductor 120 and the capacitor 110 may be designed so as to have the shortest distance therebetween to decrease noise and prevent the self resonant frequency (SRF) from being changed, thereby preventing the range of the inductor available in the low frequency from being limited.

Meanwhile, as the size of the composite electronic composite is decreased, the internal magnetic layer for blocking the magnetic field of the inductor is increasingly thinned, thereby causing the problem in that Q characteristics are decreased.

The Q characteristics mean a loss of an element or efficiency reduction, which means that the larger the Q value, the lower the loss and the higher the efficiency become.

For instance, according to the exemplary embodiment in the present disclosure, the capacitor 110 is bonded to the side surface of the inductor 120 to significantly decrease the effect of each component on each other, thereby preventing the Q characteristics of the components from deteriorating.

FIG. 7 is a view illustrating a driving power supply system supplying driving power to a predetermined terminal requiring the driving power through a battery and a power manager.

Referring to FIG. 7, the driving power supplying system may include a battery 300, a first power stabilizer 400, a power manager 500, and a second power stabilizer 600.

The battery 300 may supply power to the power manager 500. Here, the power supplied to the power manager 500 by the battery 300 will be defined as first power.

The first power stabilizer 400 may stabilize the first power V₁ and supply the stabilized first power to the power manager 500. In detail, the first power stabilizer 400 may include a capacitor C₁ formed between a connection terminal between the battery 300 and the power manager 500 and a ground. The capacitor C₁ may decrease noise included in the first power.

In addition, the capacitor C₁ may be charged with electric charges. In addition, in the case in which the power manager 500 instantaneously consumes a large amount of current, the capacitor C₁ may discharge the electric charges charged therein, thereby suppressing a voltage variation in the power manager 500.

It may be preferable that the capacitor C₁ is a high capacitance capacitor in which the number of stacked dielectric layers is equal to or more 300.

The power manager 500 may serve to convert power input to the electronic apparatuses into power appropriate for the electronic apparatus and distribute, charge, and control the power. Therefore, the power manager 500 may generally include a DC to DC converter.

In addition, the power manager 500 may be implemented as the power management integrated circuit (PMIC).

The power manager 500 may convert the first power V₁ into second power V₂. The second power V₂ may be required by an active device such as an integrated circuit (IC), or the like, connected to an output terminal of the power manager 500 to receive the driving power from the power manager 500.

The second power stabilizer 600 may stabilize the second power V₂ and transfer the stabilized second power to an output terminal V_{dd}. The active device such as an integrated circuit (IC), or the like, receiving the driving power from the power manager 500 may be connected to the output terminal V_{dd}.

In detail, the second power stabilizer 600 may include an inductor L₁ disposed between the power manager 500 and the output terminal V_{dd} and connected to the power manager 500 and the output terminal V_{dd} in series. In addition, the second power stabilizer 600 may include a capacitor C₂ formed between a connection terminal between the power manager 500 and the output terminal V_{dd} and a ground.

The second power stabilizer 600 may decrease noise included in the second power V₂.

In addition, the second power stabilizer 600 may stably supply power to the output terminal V_{dd}.

The inductor L₁ may preferably be a power inductor that may be used with a large amount of current.

The power inductor may be a high efficiency inductor in which inductance is changed in an amount less than a general inductor when a DC current is applied thereto. For instance, the power inductor may include the DC bias characteristics (change in inductance depending on the applied DC current) as well as the functions of the general inductor.

In addition, the capacitor C₂ may be preferably a high capacitance capacitor.

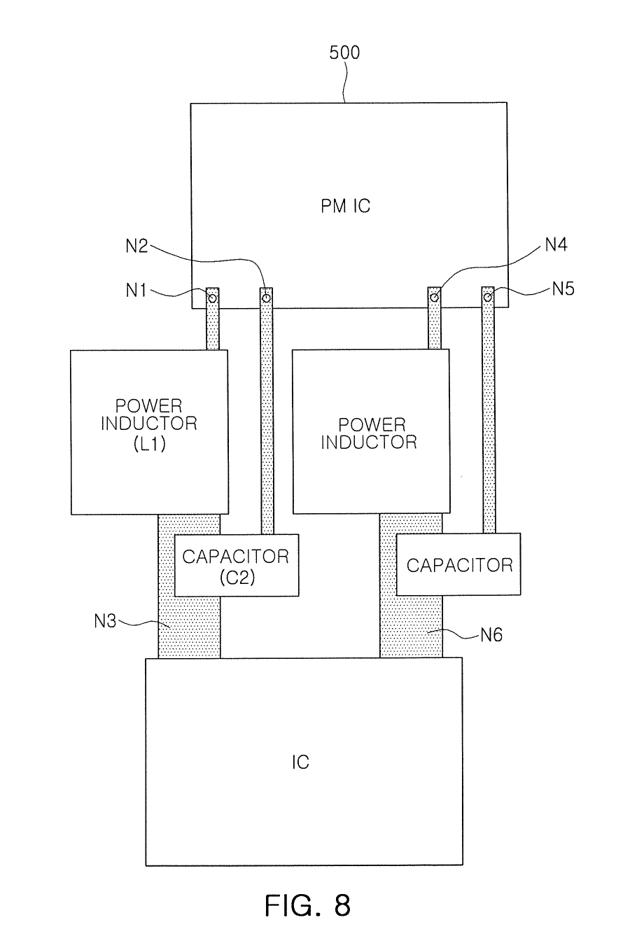

FIG. 8 is a view illustrating a disposition pattern of the driving power supply system.

Referring to FIG. 8, a pattern in which the power manager 500, the power inductor L₁, and the second capacitor C₂ are disposed may be confirmed.

In general, the power manager (PMIC) 500 may include several to tens of DC to DC converters. In addition, in order to implement a function of the DC to DC converter, a power inductor and a high capacitance capacitor may be required in each DC to DC converter.

Referring to FIG. 8, the power manager 500 may have predetermined terminals N1 and N2. The power manager 500 may receive power from the battery and convert the power using the DC to DC converter. In addition, the power manager 500 may supply the converted power through the first terminal N1. The second terminal N2 may be a ground terminal.

Here, the first power inductor L₁ and the second capacitor C₂ may receive power from the first terminal N1, stabilize the power, and supply driving power through a third terminal N3. Therefore, the first power inductor L₁ and the second capacitor C₂ may serve as the second power stabilizer.

Since fourth to sixth terminals N4 to N6 illustrated in FIG. 8 perform the same functions as those of the first to third terminals N1 to N3, a detailed description thereof will be omitted.

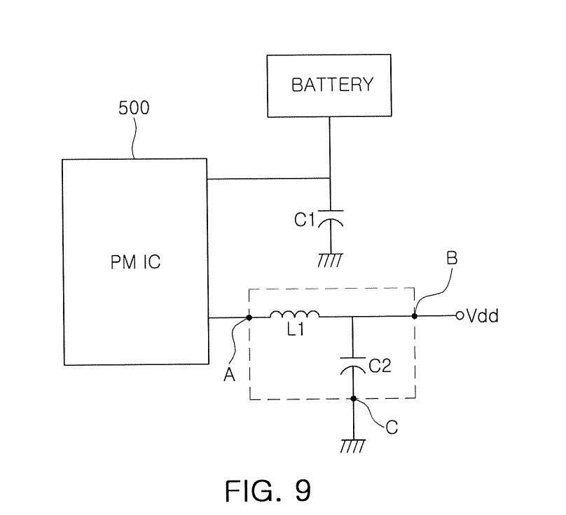

FIG. 9 is a circuit diagram of the composite electronic component according to the exemplary embodiment in the present disclosure.

Referring to FIG. 9, the composite electronic component may include an input terminal part A (input terminal), the power stabilizer, an output terminal part B (output terminal), and a ground terminal part C (ground terminal).

The power stabilizer may include the power inductor L₁ and the second capacitor C₂.

The composite electronic component may perform the function of the second power stabilizer described above.

The input terminal part A may receive power converted by the power manager 500.

The power stabilizer may stabilize the power received from the input terminal part A.

The output terminal part B may supply the stabilized power to an output terminal V_{dd}.

The ground terminal part C may connect the power stabilizer to a ground.

Meanwhile, the power stabilizer may include the power inductor L₁ connected between the input terminal part A and the output terminal part B and the second capacitor C₂ connected between the ground terminal part C and the output terminal part.

Referring to FIG. 9, the power inductor L₁ and the second capacitor C₂ share the output terminal part B and thus an interval between the power inductor L₁ and the second capacitor C₂ may be decreased.

As such, the composite electronic component may be formed by implementing the power inductor and the high capacitance capacitor provided in an output power terminal of the power manager 500 as a single component. Therefore, in the composite electronic component, a degree of integration of devices may be improved.

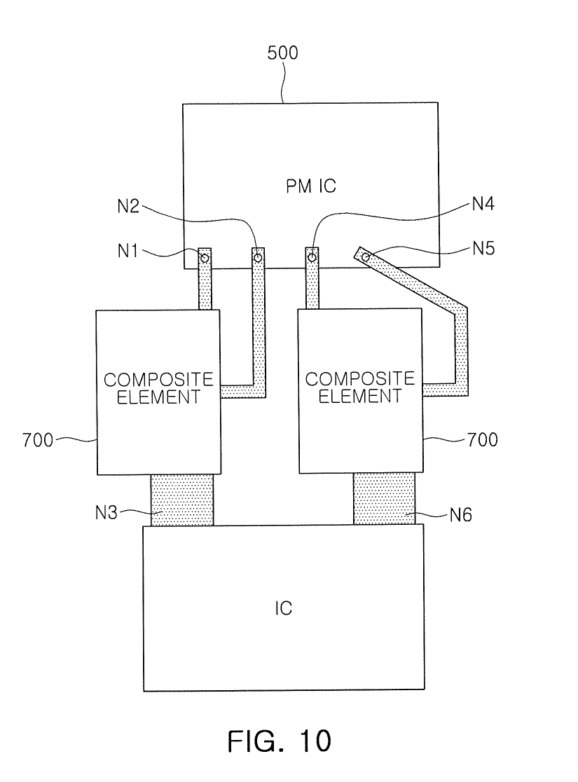

FIG. 10 is a view illustrating the disposition pattern of the driving power supply system to which the composite electronic component according to the exemplary embodiment in the present disclosure is applied.

Referring to FIG. 10, it may be confirmed that the second capacitor C₂ and the power inductor L₁ illustrated in FIG. 8 have been replaced by the composite electronic component according to an exemplary embodiment in the present disclosure.

As described above, the composite electronic component may serve as the second power stabilizer.

In addition, the second capacitor C₂ and the power inductor L₁ may be replaced by the composite electronic component according to the exemplary embodiment in the present disclosure, thereby significantly decreasing a length of a wiring. In addition, the number of disposed devices is decreased and thus the devices may be optimally disposed.

For instance, according to the exemplary embodiment in the present disclosure, the power manager, the power inductor, and the high capacitance capacitor may be disposed to be as close to each other as possible and the wiring of the power line may be designed to be short and thick, thereby decreasing noise.

Further, according to the exemplary embodiment in the present disclosure, two components (second capacitor and power inductor) are implemented as a single composite electronic component, thereby decreasing the area in which the components are mounted on the PCB. According to the present exemplary embodiment, the area in which the components are mounted may be decreased by about 30 to 60%, as compared with the existing disposition pattern.

Further, according to the exemplary embodiment in the present disclosure, the power manager 500 may supply the power to the IC receiving the driving power through the shortest wiring.

Further, according to the exemplary embodiment in the present disclosure, the composite electronic component may significantly decrease the effect of the magnetic flux generated from the inductor on the internal electrodes of the capacitor due to the capacitor disposed on the side surface of the inductor to prevent the self resonant frequency (SRF) from being changed.

Further, according to the exemplary embodiment in the present disclosure, the composite electronic component may prevent the Q characteristics of the component from deteriorating due to the capacitor disposed on the side surface of the inductor.

Board having Multilayer Ceramic Capacitor

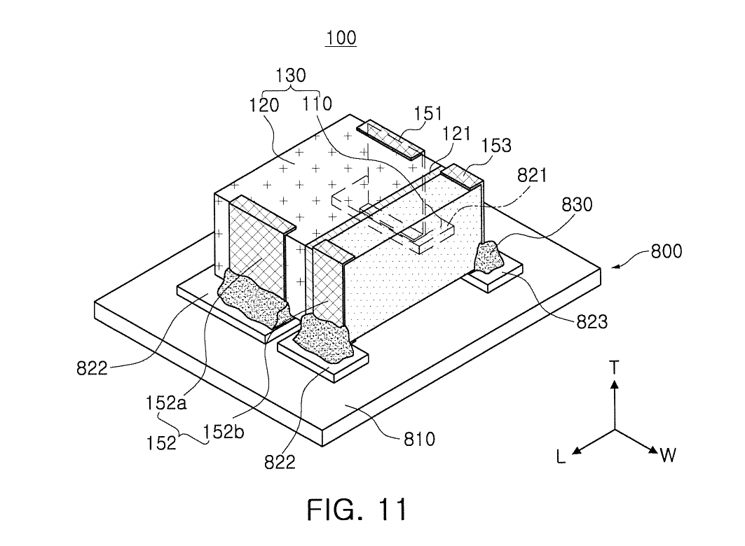

FIG. 11 is a perspective view illustrating a form in which the composite electronic component of FIG. 1 is mounted on the printed circuit board.

Referring to FIG. 11, a board 800 having a composite electronic component 100 according to the exemplary embodiment in the present disclosure may include a printed circuit board 810 on which the composite electronic component 100 is mounted and three or more electrode pads 821, 822, and 823 formed on an upper surface of the printed circuit board 810.

The electrode pads may include the first to third electrode pads 821, 822, and 823 connected to the input terminal 151, the output terminal 152, and the ground terminal 153 of the composite electronic component, respectively.

Here, the input terminal 151, the output terminal 152, and the ground terminal 153 of the composite electronic component 100 may be electrically connected to the printed circuit board 810 by solders 830 in a state in which they are positioned on the first to third electrode pads 821, 822, and 823, respectively, so as to contact the first to third electrode pads 821, 822, and 823, respectively.

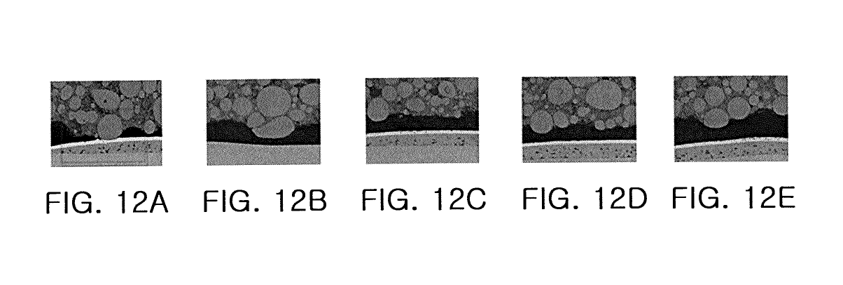

FIGS. 12A through 12E are scanning electron microscope (SEM) photographs illustrating the bonded interface between the inductor and the capacitor according to the inventive Example and Comparative Example of the present disclosure.

Referring to FIGS. 12A through 12E, FIG. 12A shows Comparative Example in which the adhesive used at the time of bonding between the inductor and the capacitor is not added with the silicon dioxide (SiO₂) and FIGS. 12B through 12E show the Inventive Examples 1 to 4 in which the inductor and the capacitor are bonded to each other using the adhesive added with 20 wt %, 30 wt %, 40 wt %, and 50 wt % of silicon dioxide (SiO₂), respectively.

It may be appreciated that in the case of FIG. 12A illustrating Comparative Example in which the silicon dioxide (SiO₂) is not added with the adhesive used at the time of bonding between the inductor and the capacitor, the inductor and the capacitor contact each other, such that the insulation resistance is leaked toward the inductor having the relatively lower insulation resistance (IR), thereby decreasing the insulation resistance of the capacitor.

On the other hand, according to the Inventive Examples 1 through 4 (FIGS. 12B through 12E), it may be appreciated that the adhesive used at the time of bonding between the inductor and the capacitor is added with 20 to 50 wt % of silicon dioxide (SiO₂) and thus the inductor and the capacitor are spaced apart from each other not to contact each other.

As a result, the inductor and the capacitor may keep a predetermined distance at the time of the bonding process, thereby improving the reduction in the insulation resistance (IR).

As set forth above, according to exemplary embodiments in the present disclosure, the composite electronic component having a decreased mounting area of component in the driving power supply system may be provided.

In addition, according to exemplary embodiments in the present disclosure, the composite electronic component capable of suppressing occurrence of noise in the driving power supply system may be provided.

Further, according to exemplary embodiments in the present disclosure, the composite electronic component may significantly decrease the effect of the inductor on the internal electrodes of the capacitor due to the capacitor disposed on the side surface of the inductor to prevent the self resonant frequency (SRF) from being changed.

Further, according to exemplary embodiments in the present disclosure, the composite electronic component may prevent the Q characteristics of the component from deteriorating due to the capacitor disposed on the side surface of the inductor.

Further, according to exemplary embodiments in the present disclosure, the inductor and the capacitor may be bonded to each other using the adhesive including the thermosetting resin to which silicon dioxide (SiO₂) is added to constantly keep the distance between the inductor and the capacitor at the time of the bonding process, thereby improving the reduction in the insulation resistance (IR).

While exemplary embodiments have been shown and described above, it will be apparent to those skilled in the art that modifications and variations could be made without departing from the spirit and scope of the present disclosure as defined by the appended claims.

What is claimed is:

1. A composite electronic component, comprising:
a composite body including a capacitor and an inductor bonded to each other, the capacitor including a ceramic body in which a plurality of dielectric layers and first and second internal electrodes disposed to face each other with respective dielectric layers interposed between the first and second internal electrodes are stacked and the inductor including a magnetic body including a coil part;
an input terminal disposed on a first end surface of the composite body in a length direction and connected to the coil part of the inductor;
an output terminal including a first output terminal disposed on a second end surface of the composite body in the length direction and connected to the coil part of the inductor and a second output terminal disposed on the second end surface of the composite body in the length direction and connected to the first internal electrodes of the capacitor; and
a ground terminal disposed on the first end surface of the composite body in the length direction and connected to the second internal electrodes of the capacitor,
wherein the inductor and the capacitor are bonded to each other by an adhesive including a thermosetting resin containing silicon dioxide (SiO₂).

2. The composite electronic component of claim 1, wherein the thermosetting resin is an epoxy resin.

3. The composite electronic component of claim 1, wherein the silicon dioxide (SiO₂) is in an amount of 20 to 50 wt % of the adhesive.

4. The composite electronic component of claim 1, wherein the inductor and the capacitor are spaced apart from each other by the adhesive.

5. The composite electronic component of claim 1, wherein the magnetic body has a form in which a plurality of magnetic layers having conductive patterns formed thereon are stacked and the conductive patterns configure the coil part.

6. The composite electronic component of claim 1, wherein the inductor has a thin film form in which the magnetic body includes an insulating substrate and a coil formed on at least one surface of the insulating substrate.

7. The composite electronic component of claim 1, wherein the magnetic body includes a core and a winding coil wound around the core.

8. The composite electronic component of claim 1, wherein the capacitor is bonded to a side surface of the inductor.

9. The composite electronic component of claim 1, wherein the coil part is wounded around an axis parallel to the adhesive.

10. The composite electronic component of claim 1, wherein the input terminal and the first output terminal, and the ground terminal and the second output terminal are disposed at opposite sides of the adhesive.

11. A composite electronic component, comprising:
an input terminal receiving power converted by a power manager;
a power stabilizer stabilizing the received power and including a composite body including a capacitor and an inductor bonded to each other, the capacitor including a ceramic body in which a plurality of dielectric layers and first and second internal electrodes disposed to face each other with respective dielectric layers interposed between the first and second internal electrodes are stacked, the inductor including a magnetic body including a coil part, and the inductor and the capacitor being bonded to each other by an adhesive including a thermosetting resin containing silicon dioxide (SiO₂);
an output terminal supplying the stabilized power; and
a ground terminal for grounding.

12. The composite electronic component of claim 11, wherein the input terminal is disposed on a first end surface of the composite body in a length direction,
the output terminal includes a first output terminal disposed on a second end surface of the composite body in the length direction and connected to the coil part of the inductor and a second output terminal disposed on the second end surface of the composite body in the length direction and connected to the first internal electrodes of the capacitor, and
the ground terminal is disposed on the first end surface of the composite body in the length direction and is connected to the second internal electrodes of the capacitor.

13. The composite electronic component of claim 12, wherein the input terminal and the first output terminal, and the ground terminal and the second output terminal are disposed at opposite sides of the adhesive.

14. The composite electronic component of claim 11, wherein the capacitor is bonded to a side surface of the inductor.

15. The composite electronic component of claim 11, wherein the thermosetting resin is an epoxy resin.

16. The composite electronic component of claim 11, wherein the silicon dioxide (SiO₂) is added in an amount of 20 to 50 wt % of the adhesive.

17. The composite electronic component of claim 11, wherein the inductor and the capacitor are spaced apart from each other by the adhesive.

18. The composite electronic component of claim 11, wherein the coil part is wounded around an axis parallel to the adhesive.

19. A composite electronic component, comprising:
a composite body including a capacitor and an inductor bonded to each other by an adhesive including a thermosetting resin containing silicon dioxide (SiO₂), the capacitor including a ceramic body in which a plurality of dielectric layers and first and second internal electrodes disposed to face each other with respective dielectric layers interposed between the first and second internal electrodes are stacked and the inductor including a magnetic body including a coil part;
first and second terminals disposed spaced-apart from each other on a first end surface of the composite body and respectively connected to a first end of the coil part of the inductor and the second internal electrodes of the capacitors; and
third and fourth terminals disposed on a second end surface of the composite body opposite to the first end surface and respectively connected to a second end of the coil part of the inductor and the first internal electrodes of the capacitor.

20. The composite electronic component of claim 19, wherein the silicon dioxide (SiO₂) is in an amount of 20 to 50 wt % of the adhesive.
